(19) United States
(12) Patent Application Publication
(10) Pub. No.: US 2011/0180861 A1
(43) Pub. Date: Jul. 28, 2011

(54) MAGNETIC RANDOM ACCESS MEMORY HAVING MAGNETORESISTIVE EFFECT ELEMENT

(75) Inventor: Masayoshi IWAYAMA, Kawasaki-shi (JP)

(73) Assignee: KABUSHIKI KAISHA TOSHIBA, Tokyo (JP)

(21) Appl. No.: 12/769,562

(22) Filed: Apr. 28, 2010

(30) Foreign Application Priority Data
Jan. 28, 2010 (JP) 2010-017262

(51) Int. Cl. H01L 29/68

(52) U.S. Cl. 257/295; 257/E29.17

(57) ABSTRACT

A magnetic random access memory includes the following structure. A first magnetoresistive effect element is formed on a semiconductor substrate. The first magnetoresistive effect element includes a first fixed layer, a first nonmagnetic layer and a first free layer. The first fixed layer has an invariable magnetization direction. The first nonmagnetic layer is formed on the first fixed layer. The first free layer is formed on the first nonmagnetic layer and has a variable magnetization direction. An active region is formed on the substrate. A first select transistor includes a first diffusion region and a second diffusion region which are formed in the active region. The first diffusion region is electrically connected to the first free layer. A second select transistor includes the first diffusion region and a third diffusion region which are formed in the active region. A first interconnect layer is electrically connected to the first fixed layer.

### CROSS-REFERENCE TO RELATED APPLICATIONS

This application is based upon and claims the benefit of priority from prior Japanese Patent Application No. 2010-017262, filed Jan. 28, 2010, the entire contents of which are incorporated herein by reference.

### BACKGROUND OF THE INVENTION

1. Field of the Invention

The present invention relates to the layout of a memory cell array in a magnetic random access memory (hereinafter abbreviated as an MRAM).

2. Description of the Related Art

An MRAM is a generic name of nonvolatile solid-state memories which use a resistance change in a barrier layer dependent on the magnetization direction of a ferromagnet and which permit stored information to be retained and read at any time. A memory cell in the MRAM generally includes a magnetoresistive effect element (hereinafter referred to as a magnetic tunnel junction (MTJ) element) which has a stack structure of a plurality of ferromagnetic layers (a free layer, a fixed layer) and a barrier layer located between the ferromagnetic layers, and also includes a select transistor (cell transistor). The free layer has a variable magnetization direction, while the fixed layer has an invariable magnetization direction.

Recently, there has been proposed a spin injection type MRAM using a spin transfer torque (STT) writing scheme. In the spin injection type MRAM, a current is directly applied to an MTJ element, and the magnetization direction of a free layer is changed by the direction of the current, thereby writing information.

The STT writing is characterized in that the writing current is higher when the relative magnetization directions of the free layer and fixed layer change from a parallel state to an antiparallel state than when the relative magnetization directions change from an antiparallel state to a parallel state.

From the perspective of fabrication, it is desirable that the MTJ element of the memory cell be structured to have the free layer above the barrier layer and to have the fixed layer under the barrier layer.

On the other hand, in the above-mentioned structure having the free layer above the barrier layer and having the fixed layer under the barrier layer, there is concern that a drive current decreases due to the application of a higher back bias effect to the select transistor in the case of writing from a parallel state to an antiparallel state that requires a higher drive current. Moreover, it has become apparent that thermostability of the MTJ element is generally proportional to an inversion current density.

Thus, if an ideal layout of a memory cell array is obtained, it is difficult to invert the magnetization of the MTJ element having sufficient thermostability by spin injection in the case of a current drive current of the select transistor. Thus, the problem is that the gate width of the select transistor, that is, the area of the memory cell has to be increased.

Furthermore, as a related art of the present invention, Jpn. Pat. Appln. KOKAI Publication No. 2008-47220 has disclosed the layout of a memory cell array of a spin injection type random access memory having a double gate structure. Using a future size (F), the area of one memory cell in the above-mentioned layout can be represented by 8 F²/cell. F is half the pitch of word lines/bit lines (half pitch), and the half pitch is set at a minimum fabrication dimension.

### BRIEF SUMMARY OF THE INVENTION

According to an aspect of the present invention, there is provided a magnetic random access memory comprising: a first magnetoresistive effect element on a semiconductor substrate, the first magnetoresistive effect element including a first fixed layer, a first nonmagnetic layer and a first free layer, the first fixed layer having an invariable magnetization direction, the first nonmagnetic layer being formed on the first fixed layer, the first free layer being formed on the first nonmagnetic layer and having a variable magnetization direction; an active region on the semiconductor substrate; a first select transistor including a first diffusion region and a second diffusion region which are formed in the active region, the first diffusion region being electrically connected to the first free layer; a second select transistor including the first diffusion region and a third diffusion region which are formed in the active region; and a first interconnect layer electrically connected to the first fixed layer.

### BRIEF DESCRIPTION OF THE SEVERAL VIEWS OF THE DRAWING

FIG. 1A is a simple circuit diagram of a memory cell including an MTJ element;

FIG. 1B is a simple circuit diagram of a memory cell including the MTJ element;

FIG. 2 is a circuit diagram of an MRAM according to a first embodiment of the present invention;

FIG. 3 is a sectional view partially showing a current path in the MRAM according to the first embodiment;

FIG. 4 is a layout view of a memory cell array in the MRAM according to the first embodiment;

FIG. 5 is a layout view showing, on a manufacturing step basis, the main parts of the layout shown in FIG. 4;

FIG. 6 is a layout view showing, on a manufacturing step basis, the main parts of the layout shown in FIG. 4;

FIG. 7 is a layout view showing, on a manufacturing step basis, the main parts of the layout shown in FIG. 4;

FIG. 8A is a sectional view taken along the line A-A′ in FIG. 4;

FIG. 8B is a sectional view taken along the line B-B′ in FIG. 4;

FIG. 8C is a sectional view taken along the line C-C′ in FIG. 4;

FIG. 8D is a sectional view taken along the line D-D′ in FIG. 4;

FIG. 9 is a sectional view showing characteristic parts of an MRAM according to a second embodiment of the present invention;

FIG. 10 is a layout view of a memory cell array in an MRAM according to a third embodiment of the present invention; and

FIG. 11 is a sectional view showing characteristic parts of the MRAM according to the third embodiment.

### DETAILED DESCRIPTION OF THE INVENTION

Embodiments of the present invention will be described hereinafter with reference to the drawings. It is to be noted that the same signs are used for the same or similar components throughout the embodiments described below to avoid redundant explanations and that such components are not repeatedly described in detail.

### First Embodiment

An MRAM according to a first embodiment of the present invention is described.

The MRAM includes a plurality of memory cells. Each of the memory cells has a magnetoresistive effect element (MTJ element) and a select transistor.

First, a structure of the MTJ element desirable from the perspective of its fabrication is described. The MTJ element comprises at least a free layer (or a recording layer), a fixed layer (or a reference layer), and a barrier layer between the free layer and the fixed layer. The barrier layer is made of a nonmagnetic material. For example, an insulator, a semiconductor or a metal is used for the barrier layer.

An element used for the MTJ element is a material difficult to etch, and volatile etching of this element is difficult. In general, this element is often processed by physical etching such as ion milling.

However, it is well known that unprocessed substances after the physical etching re-adhere to the MTJ element and thereby cause, for example, an increased element dimension, a short-circuit failure between the free layer and the fixed layer, and an increased element dimension after processing.

In order to overcome this problem, it is desirable to provide a structure in which the free layer is disposed above the barrier layer on a substrate and the fixed layer is disposed under the barrier layer and to process the barrier layer and the fixed layer simultaneously with a lower electrode after processing the free layer alone.

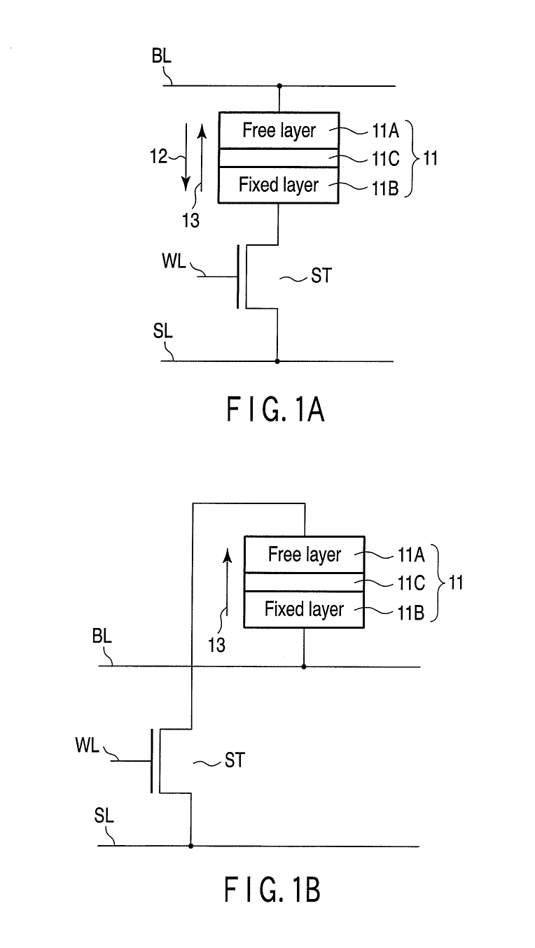

FIG. 1A shows a simple circuit diagram of the memory cell in which the MTJ element has the above-mentioned structure.

The memory cell comprises a bit line BL, an MTJ element 11, a select transistor ST having a word line WL, and a source line SL. The MTJ element 11 has a free layer 11A, a fixed layer 11B, and a barrier layer 11C between the free layer 11A and the fixed layer 11B.

The magnetization direction of the fixed layer 11B is invariable, while the magnetization direction of the free layer 11A is variable. That is, the magnetization direction of the fixed layer 11B is fixed in a given direction. The magnetization direction of the free layer 11A can be changed to a direction parallel or antiparallel to the magnetization direction of the fixed layer 11B.

In the structure shown in FIG. 1A, the voltage of the bit line BL is set at “high” and the voltage of the source line SL is set at “low” in order to invert the relative magnetization directions of the free layer 11A and the fixed layer 11B from antiparallel directions to parallel direction, that is, in order to write from “1” into “0”. Thus, a write current runs in the direction of 12 indicated in FIG. 1A, that is, from the free layer 11A to the fixed layer 11B.

On the other hand, in order to invert the relative magnetization directions of the free layer 11A and the fixed layer 11B from parallel directions to antiparallel directions, that is, in order to write from “0” into “1”, the voltage of the bit line BL is set at “low” and the voltage of the source line SL is set at “high”. Thus, a write current runs in the direction of 13 indicated in FIG. 1A, that is, from the fixed layer 11B to the free layer 11A. In this case, the voltage applied to the MTJ element 11 is equivalent to the application of a negative voltage of the substrate, so that the drive current (write current) of the select transistor ST is significantly reduced (back bias effect).

In the meantime, it has become apparent that a higher current is needed to invert the magnetization direction from a parallel state to an antiparallel state than to invert the magnetization direction from an antiparallel state to a parallel state due to the asymmetry of spin transfer torque.

Although a high current is needed to invert the relative magnetization directions from a parallel state to an antiparallel state as described above, there is a problem of the drive current of the select transistor ST that is reduced by the above-mentioned back bias effect.

The gate width of the select transistor ST has to be increased to solve such a problem. However, the increase of the gate width leads to problems such as an increased area of the memory cell and difficulty in enhancing integration.

In order to solve this problem, the use of the circuit configuration as shown in FIG. 1B is conceivable.

As shown in FIG. 1B, one end of the select transistor is connected to the free layer 11A of the MTJ element 11. Further, the bit line BL is connected to the fixed layer 11B of the MTJ element 11.

In such a circuit configuration, the voltage of the bit line BL is set at “high” and the voltage of the source line SL is set at “low” in order to invert the relative magnetization directions of the free layer 11A and the fixed layer 11B from parallel directions to antiparallel directions. Thus, a write current runs in the direction of 13 indicated in FIG. 1B. In this case, there is no problem of the drive current of the select transistor ST that is reduced by the above-mentioned back bias effect.

That is, if the circuit shown in FIG. 1B is used, the write current is not reduced by the back bias effect when the relative magnetization directions are inverted from parallel directions to antiparallel directions and when a high current is needed.

However, even if the current direction required for the inversion of the magnetization direction is taken into consideration to address the problem of the drive current that is reduced by the back bias effect as described above, there is also a problem of an insufficient write current to ensure good thermostability of the MTJ element. Thermostability is low when the write current (inversion current) is low, while thermostability is high when the write current is high. Owing to such characteristics, the write current has to be further increased to enhance thermostability.

Therefore, in order to solve this problem, the following circuit configuration is used in the first embodiment.

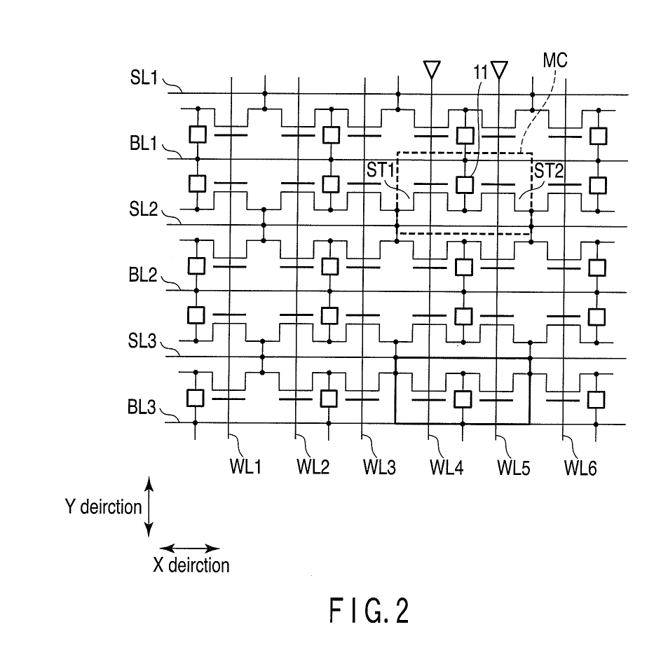

FIG. 2 is a circuit diagram of the MRAM according to the first embodiment. FIG. 2 shows a circuit diagram of a memory cell array of a double gate structure in which memory cells adjacent to a source line shares this source line to enable the use of two active word lines.

As shown in FIG. 2, source lines SL1 to SL3 and bit lines BL1 to BL3 extending in an X direction are alternately arranged in a Y direction. A memory cell MC is provided at the intersection of the adjacent bit line BL and source line SL and adjacent two word lines WL. Thus, a plurality of memory cells MC are arranged in matrix form.

One memory cell MC has an MTJ element 11, and two select transistors ST1, ST2. The select transistors ST1, ST2 are configured by, for example, MOS field effect transistors. The select transistors ST1, ST2 are connected in parallel between one end (free layer) of the MTJ element 11 and the source line SL. The other end (fixed layer) of the MTJ element 11 is connected to the bit line BL. The memory cells MC having such a configuration are repetitively arranged along the X direction.

The select transistors ST1, ST2 of two memory cells MC adjacent along the Y direction are connected to the common source line SL. Specifically, the select transistors ST1, ST2 of the first memory cell MC and the select transistors ST1, ST2 of the second memory cell MC adjacent to the first memory cell MC along the Y direction are connected on one end to the common source line SL. In addition, the select transistors ST1, ST2 of the memory cells MC are connected on the other end to one end of the MTJ element 11.

The other end of the MTJ element 11 of the first memory cell MC and the other end of the MTJ element 11 of the third memory cell MC adjacent to the second memory cell on the opposite side of the first memory cell MC along the Y direction are connected to the common bit line BL.

Furthermore, gate electrodes of the select transistors ST1 of the memory cells MC arranged in the same column (Y direction) are connected by the word line. Gate electrodes of the select transistors ST2 of the memory cells MC arranged in the same column are also connected by the word line.

In accordance with this arrangement, one unit structure is constituted by two rows of memory cell groups connected between three consecutive lines: the bit line BL, the source line SL and the bit line BL. Such unit structures are repetitively arranged along the Y direction.

By way of example, a case is described in which data is written into the memory cell MC disposed at the intersection of the adjacent source line SL3 and bit line BL3 and the adjacent word lines WL4, WL5 in the MRAM shown in FIG. 2.

The word lines WL4, WL5 are set at “high” to turn on the select transistors ST1, ST2. Then, the source line SL3 is set at “high”, and the bit line BL3 is set at “low”. At this point, when viewed from the source line SL3, the bit line BL or the source line SL extending to the array end from the adjacent bit line which is not the bit line BL3 is set at “high”.

When the voltages are set as described above, the MTJ element 11 can be supplied with about two times as high write current as a write current in the case of one select transistor with no increase in the area of the memory cell.

However, as described above, from the perspective of the reduction of the area of the memory cell and the enhancement of the integration of the memory cell, it is difficult to arrange the memory cell array of the double gate structure after the direction of the write current is taken into consideration to suppress the back bias effect.

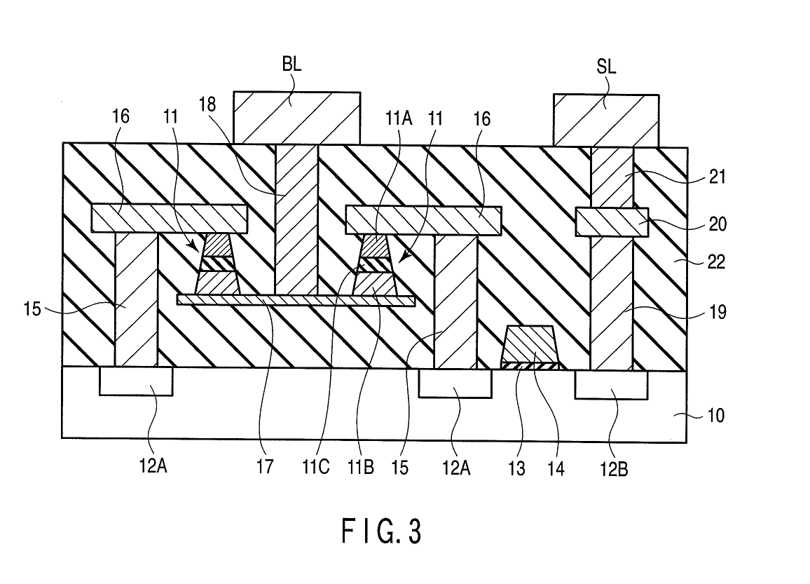

FIG. 3 is a sectional view partially showing a current path in the MRAM according to the first embodiment. In addition, FIG. 3 only partially shows a diagram in which sections of the current path are joined together for convenience of explanation. The present invention is not limited to this.

Diffusion regions (source/drain regions) 12A, 12B are formed in an active region (or element region) of a semiconductor substrate 10. A gate insulating film 13 is formed on the active region between the diffusion regions 12A, 12B, and a gate electrode 14 is formed on the gate insulating film 13.

A contact plug 15 is formed on the diffusion region 12A, and an upper electrode 16 is formed on the contact plug 15.

Furthermore, a lower electrode 17 is formed under the semiconductor substrate 10. The MTJ element 11 is formed on one portion of the lower electrode 17, and the upper electrode 16 is disposed on the MTJ element 11. A via plug (or contact plug) 18 is formed on the center of the lower electrode 17. The bit line BL is formed on the via plug 18.

The MTJ element 11 is formed on the other portion of the lower electrode 17, and the upper electrode 16 is disposed on the MTJ element 11. Further, the contact plug 15 is formed between the upper electrode 16 and the diffusion region 12A.

Furthermore, a contact plug 19 is formed on the diffusion region 12B. A first wiring layer 20 is formed on the contact plug 19, and a via plug (or contact plug) 21 is formed on the first wiring layer 20. The source line SL is formed on the via plug 21. Further, an interlayer insulating film 22 is formed between the semiconductor substrate 10 and the bit line BL as well as the source line SL.

The MTJ element 11 is composed of the fixed layer 11B, the barrier layer 11C and the free layer 11A that are formed on the lower electrode 17 in order. In addition, the fixed layer 11B may be included in the lower electrode 17.

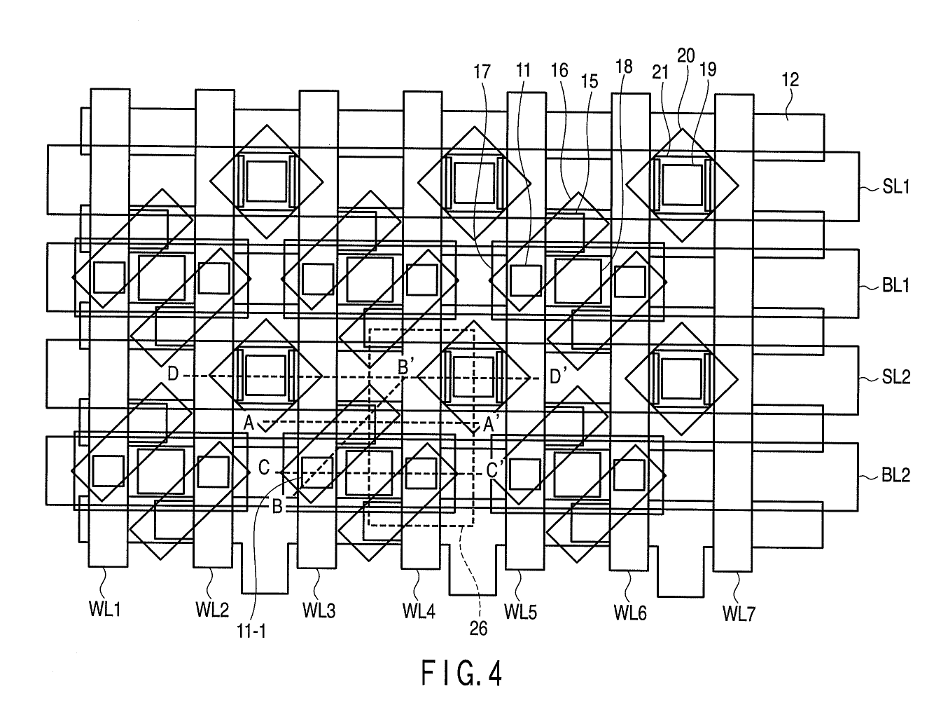

FIG. 4 is a diagram showing the layout of the memory cell array in the MRAM according to the first embodiment. In this layout, an active region 12 is ladder-shaped, and the upper electrode 16 is not perpendicular to the word line WL and the bit line BL.

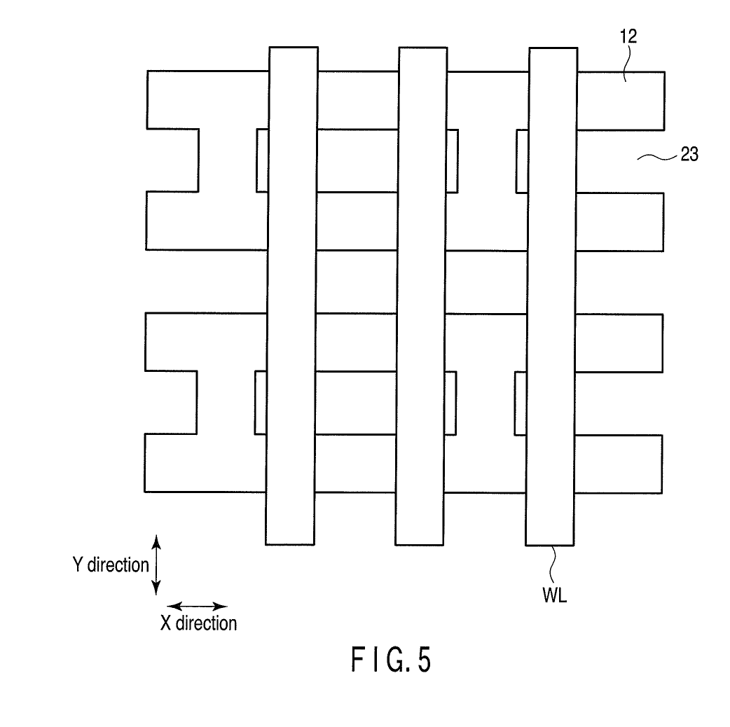

In order to explain in detail the layout shown in FIG. 4, the main parts of the layout are extracted and the layout is shown on a manufacturing step basis in FIG. 5 to FIG. 7.

FIG. 5 shows a layout after the active region and the word lines are formed.

The active region 12 and an element separation insulating region 23 are formed in the surface region of the semiconductor substrate 10. The element separation insulating region 23 is configured by, for example, shallow trench isolation (STI). The STI is formed by embedding, for example, a silicon oxide film in a trench provided in the surface region on the semiconductor substrate 10.

The active region 12 is ladder-shaped. That is, the active region 12 has two first and second rectangular regions longitudinally arranged in the X direction (first direction), and a third rectangular region formed between the two first and second rectangular regions in the Y direction (second direction) perpendicular to the X direction. In other words, the active region 12 has the first and second regions extending in the X direction, and the third region disposed between the first and second regions in the Y direction that intersects with the X direction. Moreover, the ladder-shaped active regions 12 are arranged at predetermined intervals in the Y direction.

The word lines WL extending in the Y direction are formed on the active region 12. The word lines WL are arranged at predetermined intervals in the X direction.

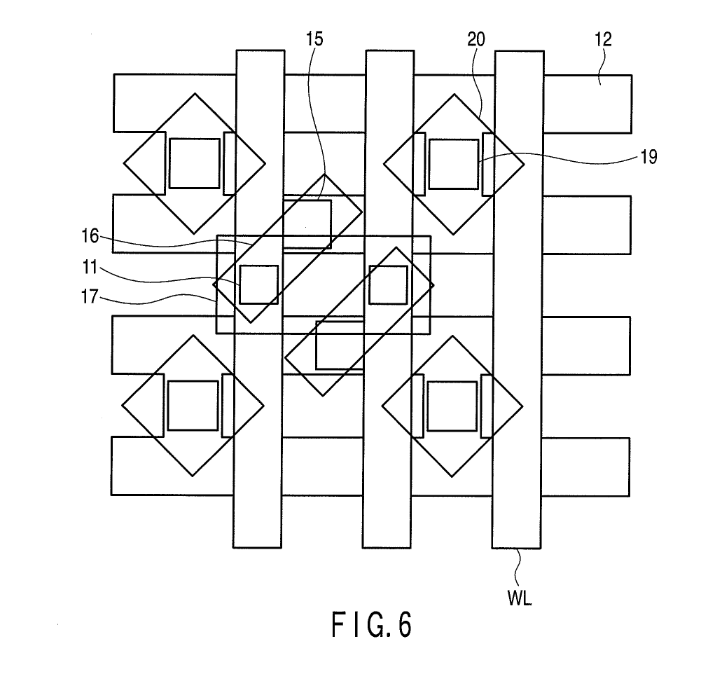

FIG. 6 shows a layout after the lower electrode 17, the MTJ element 11, the contact plug 15, the upper electrode 16, the contact plug 19 and the first wiring layer 20 are formed on the structure shown in FIG. 5.

The lower electrode 17 is formed on the semiconductor substrate, and two MTJ elements 11 are formed on the lower electrode 17. The lower electrode 17 is rectangular, and is longitudinally disposed in the X direction.

The contact plugs 15 are formed on the first and second rectangular regions of the active region 12. The upper electrode 16 is formed on the MTJ element 11 and the contact plug 15. The upper electrode 16 is rectangular, and is longitudinally disposed in a direction different from the X direction and the Y direction, that is, in a direction diagonal to the X direction and the Y direction. In other words, the upper electrode 16 extends in a third direction different from the X direction and the Y direction.

Furthermore, the contact plug 19 is formed on the third rectangular region of the active region 12, and the first wiring layer 20 is formed on the contact plug 19.

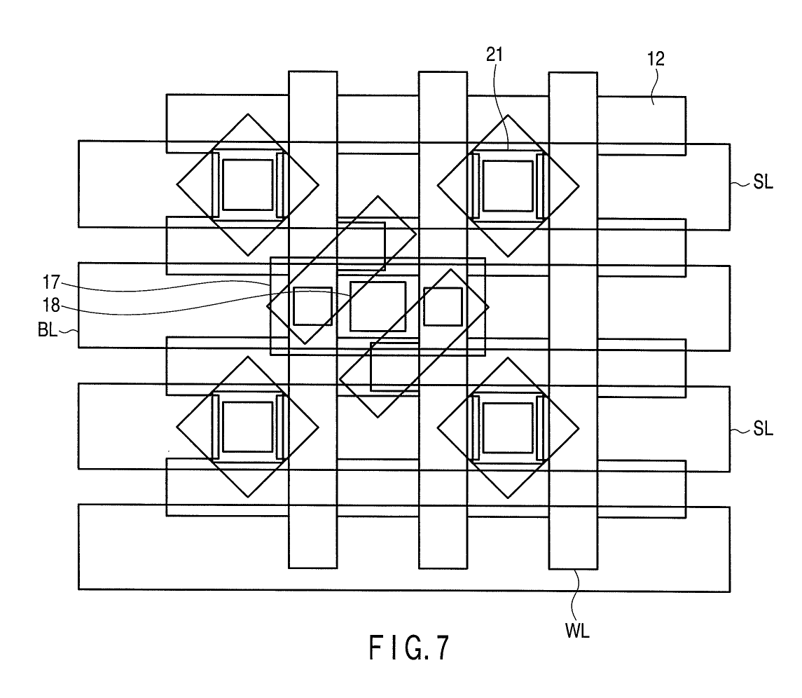

FIG. 7 shows a layout after the via plug 18, the bit line BL, the via plug 21 and the source line SL are formed on the structure shown in FIG. 6.

The via plug 18 is formed on the lower electrode 17 between two MTJ elements 11. The bit line BL is formed on the via plug 18. Moreover, the via plug 21 is formed on the first wiring layer 20. The source line SL is formed on the via plug 21.

An array of layouts shown in FIG. 7 is the layout of the memory cell array shown in FIG. 4.

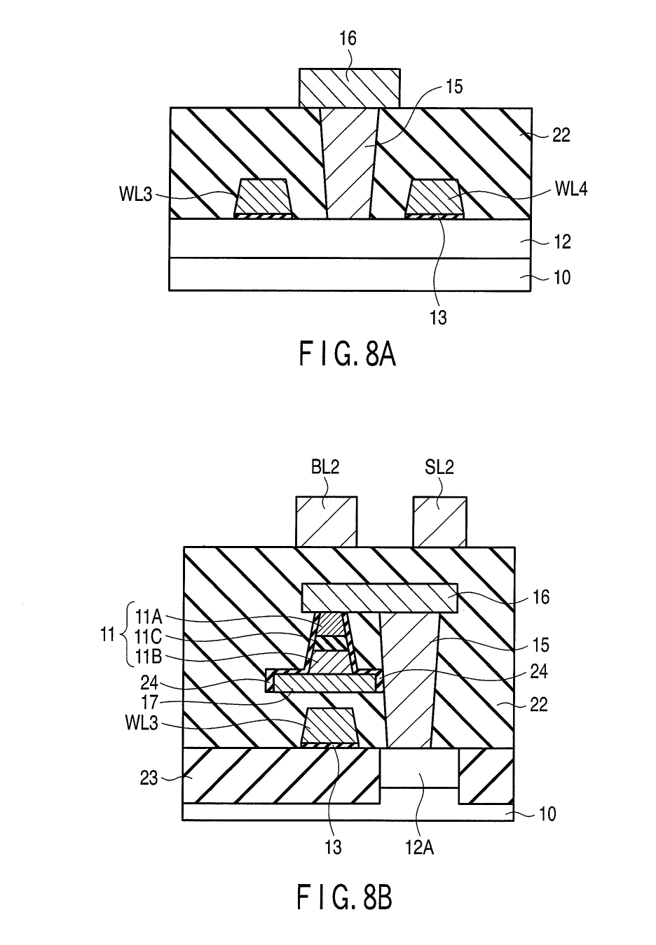

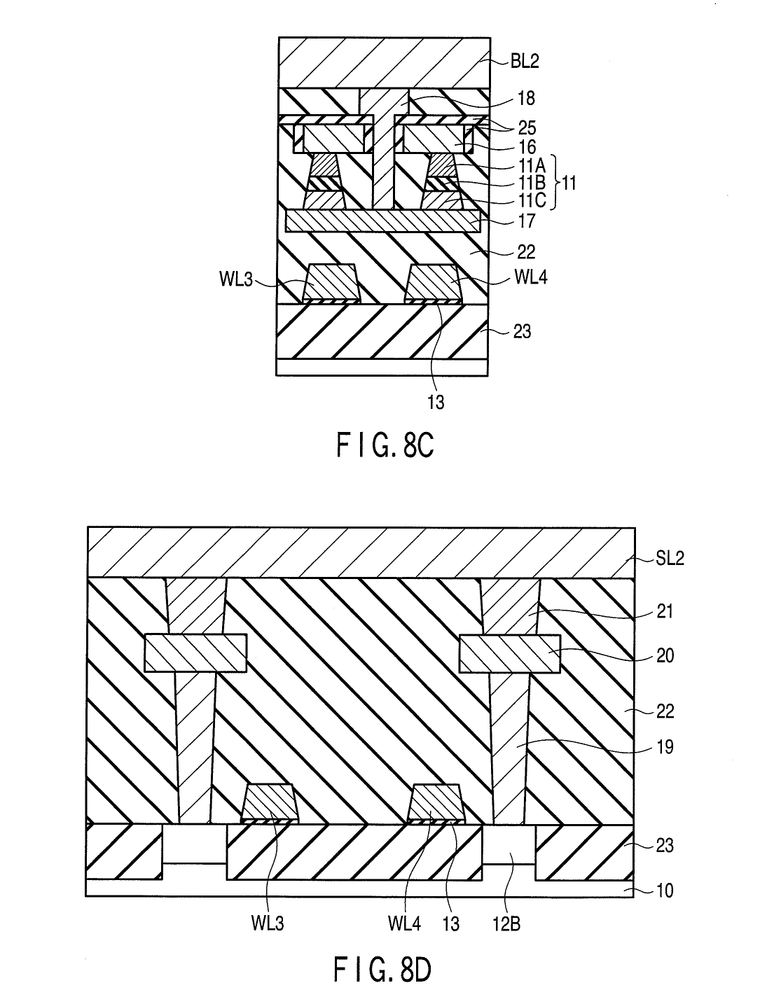

Sectional views taken along the line A-A′, the line B-B′, the line C-C′ and the line D-D′ in FIG. 4 are shown in FIG. 8A, FIG. 8B, FIG. 8C and FIG. 8D.

FIG. 8A is a sectional view taken along the line A-A′ in FIG. 4.

As shown, two select transistors are formed on the active region 12 which is formed on the semiconductor substrate 10. That is, the gate insulating film 13 is formed on the active region 12, and word lines (gate electrodes) WL3, WL4 are formed on the gate insulating film 13. The diffusion region (source/drain region) is formed in the active region 12 between the word lines WL3, WL4.

The contact plug 15 is formed on the diffusion region. The upper electrode 16 is formed on the contact plug 15. The interlayer insulating film 22 is formed on the active region 12 and the word lines WL3, WL4.

FIG. 8B is a sectional view taken along the line B-B′ in FIG. 4.

As shown, the contact plug 15 is formed on the diffusion region 12A. The upper electrode 16 is formed on the contact plug 15. The gate insulating film 13 is formed on the element separation insulating region 23 adjacent to the diffusion region 12A, and the word line WL3 is formed on the gate insulating film 13.

The lower electrode 17 is formed above the word line WL3. The MTJ element 11 is formed on the lower electrode 17. The upper electrode 16 is disposed on the MTJ element 11. A bit line BL2 and a source line SL2 are formed above the upper electrode. Moreover, the interlayer insulating film 22 is formed between the semiconductor substrate and the bit line BL2 as well as the source line SL2.

When there is no space between the contact plug 15 and the lower electrode 17, a silicon nitride film 24, for example, is deposited on the side surface of the lower electrode 17. Then, at the time of etching for a contact hole, selectivity is provided by interlayer insulating films such as a silicon oxide film and a silicon nitride film. Thus, in the formation of the contact plug 15, a contact is made between the diffusion region 12A and the contact plug 15 by self-aligning.

In this case, in order to allow for a process margin for, for example, a short-circuit failure between the lower electrode 17 and the contact plug 15, a space may be made between the lower electrode 17 and the contact plug 15, that is, the area of the memory cell may be slightly increased without using the self-aligning.

FIG. 8C is a sectional view taken along the line C-C′ in FIG. 4.

As shown, the gate insulating film 13 is formed on the element separation insulating region 23, and the word lines WL3, WL4 are formed on the gate insulating film 13. The lower electrode 17 is formed above the word lines WL3, WL4. The MTJ element 11 is formed on one potion of the lower electrode 17, and the upper electrode 16 is formed on the MTJ element 11. Similarly, the MTJ element 11 is formed on the other potion of the lower electrode 17, and the upper electrode 16 is formed on the MTJ element 11.

The via plug 18 is formed on the lower electrode 17 between the MTJ elements 11. The bit line BL2 is formed on the via plug 18. Moreover, the interlayer insulating film 22 is formed between the semiconductor substrate and the bit line BL2.

When there is no space between the via plug 18 and the upper electrode 16, a silicon nitride film 25, for example, is deposited on the side surface of the upper electrode 16. Then, at the time of etching for a contact hole, selectivity is provided by interlayer insulating films such as a silicon oxide film and a silicon nitride film. Thus, in the formation of the via plug 18, a contact is made between the upper electrode 16 and the via plug 18 by self-aligning.

In this case, in order to allow for a process margin for, for example, a short-circuit failure between the via plug 18 and the upper electrode 16, a space may be made between the upper electrode 16 and the via plug 18, that is, the area of the memory cell may be slightly increased without using the self-aligning.

FIG. 8D is a sectional view taken along the line D-D′ in FIG. 4, and shows a section of a contact portion that connects the source line SL2 and the active region.

As shown, the contact plug 19 is formed on the diffusion region 12B. The first wiring layer 20 is formed on the contact plug 19. The via plug 21 is formed on the first wiring layer 20. Moreover, the source line SL2 is formed on the via plug 21.

The gate insulating film 13 is formed on the element separation insulating region 23 adjacent to the diffusion region 12B, and the word lines WL3, WL4 are formed on the gate insulating film 13. Moreover, the interlayer insulating film 22 is formed between the semiconductor substrate and the source line SL2.

Here, the path of a write current is described referring to FIG. 8A, FIG. 8B, FIG. 8C and FIG. 8D in the case where the word lines WL3, WL4 are set at “high”, the bit line BL2 is set at “high” and the source line SL2 is set at “low” to invert the magnetization direction in an MTJ element 11-1 from a parallel state to an antiparallel state.

In the structure shown in FIG. 8C, the write current runs from the bit line BL2 to the lower electrode 17 through the via plug 18. Then, in the section shown in FIG. 8B, the write current runs from the lower electrode 17 to the diffusion region 12A through the MTJ element 11, the upper electrode 16 and the contact plug 15.

Then, in the section shown in FIG. 8A, the write current which has passed the upper electrode 16, the contact plug 15 and the diffusion region runs to the lower parts of the word lines WL3, WL4, as described above. Then, in the structure shown in FIG. 8D, the write current runs to the source line SL2 through the diffusion region 12B, the contact plug 19, the first wiring layer 20 and the via plug 21.

In the layout of the memory cell array according to the first embodiment, a unit area 26 of the memory cell is 2F wide and 4F long as shown in FIG. 4 when F is a minimum fabrication dimension, and is therefore 8 F². A size of 8 F²/cell is equal to the area of the memory cell described in Jpn. Pat. Appln. KOKAI Publication No. 2008-47220. Thus, in the layout of the memory cell array according to the present embodiment, the area of the memory cell is not increased and can be maintained.

According to the first embodiment, the following effects can be obtained.

The diffusion region (source/drain region) of the select transistor is connected to the free layer, so that no back bias effect is generated when the magnetization direction is changed from a parallel state to an antiparallel state, and the write current running to the MTJ element can be prevented from decreasing.

Furthermore, a bottom pin structure in which the fixed layer, the barrier layer and the free layer are formed in this order is provided on the semiconductor substrate. Thus, for example, the increase of element dimensions and a short-circuit failure between the free layer and the fixed layer in the manufacturing process of the MTJ element can be reduced.

Still further, the cell layout as shown in FIG. 4 is used, that is, the active region is ladder-shaped, and the upper electrode connected to the free layer is disposed in the direction (third direction) different from the direction in which the word lines, the bit lines or the source lines extend. As a result, the area necessary to form one memory cell does not increase.

Still further, the memory cell array of the double gate structure can be used to supply a write current to one MTJ element from two select transistors. Therefore, at the time of writing, the density of the write current applied to the MTJ element can be higher. This makes it possible to enhance the thermostability of the MTJ element.

### Second Embodiment

An MRAM according to a second embodiment of the present invention is described. According to the second embodiment, in the process of fabricating an MTJ element, a free layer, a barrier layer and a fixed layer are not fabricated all in the same step as shown in FIG. 8C, but the fixed layer is fabricated together with a lower electrode after the free layer is fabricated.

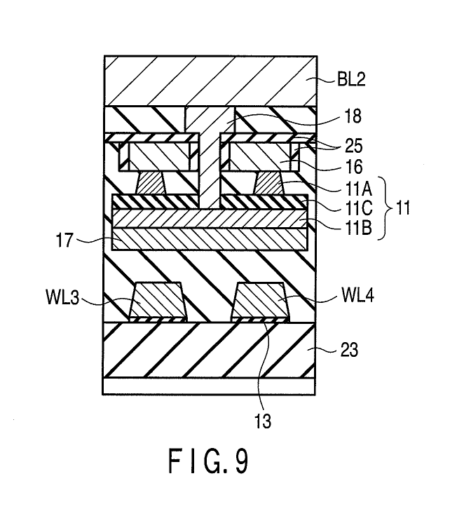

FIG. 9 is a sectional view showing characteristic parts of the MRAM according to the second embodiment, and corresponds to a section taken along the line C-C′ in FIG. 4.

As shown, a free layer 11A is different in size from a fixed layer 11B, and the free layer 11A is smaller in size than the fixed layer 11B. The size of the fixed layer 11B provided for two MTJ elements formed on a lower electrode 17 is the same as the size of the lower electrode 17.

Such a structure is formed by the following manufacturing method.

Instead of fabricating the free layer 11A, the barrier layer 11C and the fixed layer 11B in the same step, the free layer 11A is first fabricated, and then the barrier layer 11C and the fixed layer 11B are fabricated in the same step as the lower electrode 17.

When such a process is used, the increase of element dimensions and a short-circuit failure between the free layer 11A and the fixed layer 11B during the fabrication of the MTJ element can be inhibited.

The configuration and effects according to the second embodiment are similar in other respects to the configuration and effects according to the first embodiment previously described and are not described. Although the free layer alone is first fabricated in the example shown here, the free layer and the barrier layer may be first fabricated, and then the fixed layer may be fabricated together with the lower electrode.

### Third Embodiment

An MRAM according to a third embodiment of the present invention is described. According to the third embodiment, a via plug (or contact plug) 27 is formed between a contact plug 19 and a first wiring layer 20.

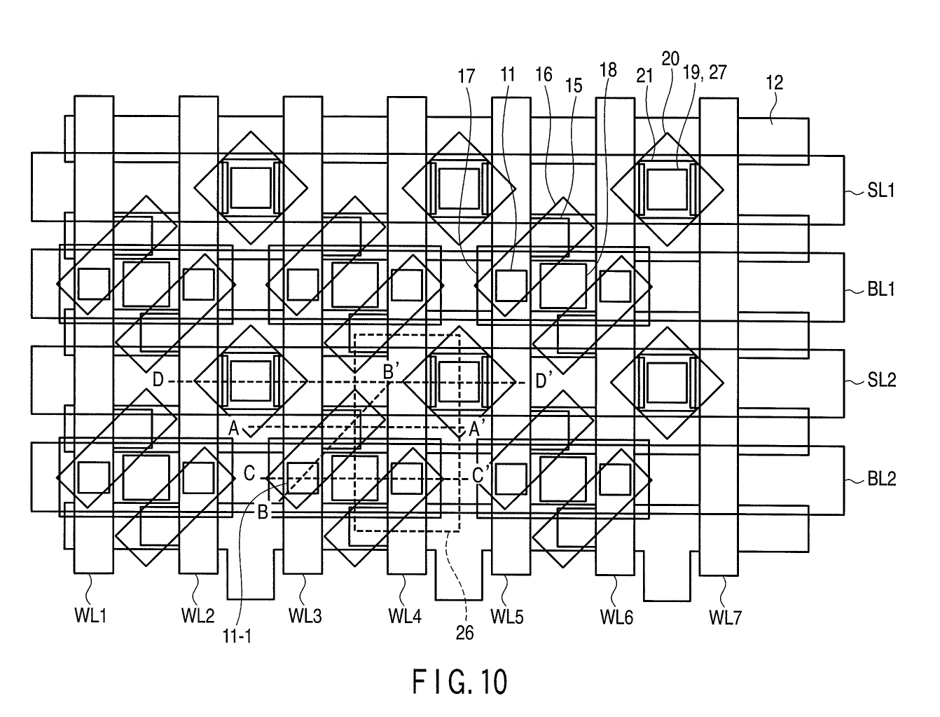

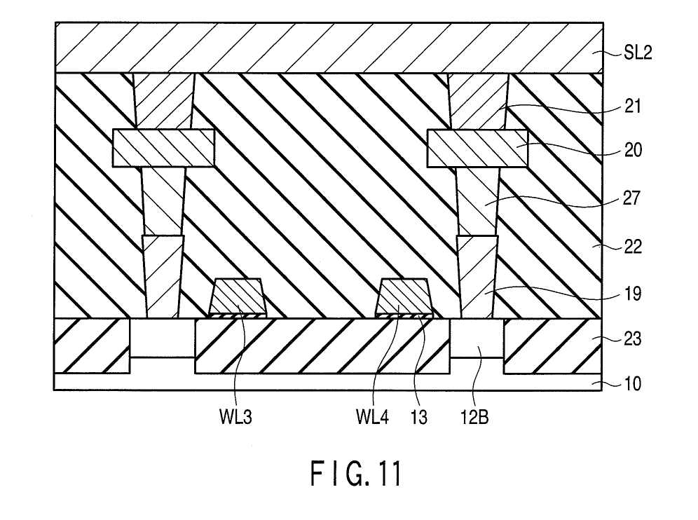

FIG. 10 is a diagram showing the layout of a memory cell array in the MRAM according to the third embodiment. FIG. 11 is a sectional view showing characteristic parts of the MRAM according to the third embodiment, and shows to a section taken along the line D-D′ in FIG. 10.

In order to embody the layout shown in the first embodiment, the contact plug 19 has to be formed after an MTJ element 11 is formed. In general, tungsten (W) is used for the contact plug 19, and tungsten is often embedded in a contact hole by a CVD method. In this case, the film formation temperature of tungsten is high, and the MTJ element 11 is therefore broken down when the MTJ element is not heat-resistant.

Thus, in the structure according to the third embodiment, the via plug 27 is formed between the contact plug 19 on a diffusion region 12B and the first wiring layer 20, as shown in FIG. 11.

The manufacturing process is as follows: The contact plug 19 is first formed, and then the MTJ element 11 is formed. Then, the via plug 27 is formed, and the first wiring layer 20 is further formed on the via plug 27. Thus, a contact is made between the diffusion region 12B and the first wiring layer 20.

When such a manufacturing process is used, the contact plug 19 is first formed, and then the MTJ element 11 is formed. This makes it possible to prevent the MTJ element 11 from being broken down by the film formation temperature of tungsten for forming the contact plug 19.

The configuration and effects according to the third embodiment are similar in other respects to the configuration and effects according to the first embodiment previously described and are not described.

According to the embodiments of the present invention, it is possible to provide a magnetic random access memory wherein the free layer is disposed on the barrier layer formed on the substrate, the direction of the write current in which there is no back bias effect is aligned with the direction of the write current when the magnetization direction of the free layer is changed from a parallel state to an antiparallel state, and the write current can be increased with no increase in the area of the memory cell.

Furthermore, according to the embodiments, the thermostability of the memory cell can be ensured with no increase in the area of the memory cell.

As described above, according to the embodiments of the present invention, it is possible to provide a magnetic random access memory wherein when the relative magnetization directions of the free layer and the fixed layer are inverted from a parallel state to an antiparallel state, the decrease of the write current due to the back bias effect of the select transistor can be prevented, and the increase in the area of the memory cell can be prevented.

It should be noted that the embodiments described above can not only be separately implemented but can also be implemented in combination properly. Moreover, the embodiments described above include various stages of the invention, and various stages of the invention can be extracted by properly combining a plurality of constituents disclosed in the embodiments.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A magnetic random access memory comprising:
a first magnetoresistive effect element on a semiconductor substrate, the first magnetoresistive effect element comprising a first fixed layer, a first nonmagnetic layer and a first free layer, the first fixed layer comprising an invariable magnetization direction, the first nonmagnetic layer being on the first fixed layer, the first free layer being on the first nonmagnetic layer and having a variable magnetization direction;
an active region on the semiconductor substrate;
a first select transistor comprising a first diffusion region and a second diffusion region in the active region, the first diffusion region being electrically connected to the first free layer;
a second select transistor comprising the first diffusion region and a third diffusion region which are in the active region; and
a first interconnect layer electrically connected to the first fixed layer.

2. The magnetic random access memory of claim 1, wherein
the active region comprises a first region, a second region and a third region, the first region and the second region being in a first direction, the third region being between the first region and the second region in a second direction not parallel with the first direction.

3. The magnetic random access memory of claim 2, further comprising:
an upper electrode on the first free layer; and
a first contact plug between the upper electrode and the first diffusion region,
wherein the upper electrode is in a third direction different from the first direction and the second direction.

4. The magnetic random access memory of claim 1, further comprising:
a lower electrode under the first fixed layer; and
a second magnetoresistive effect element on the lower electrode, a second magnetoresistive effect element comprising a second fixed layer, a second nonmagnetic layer and a second free layer, the second fixed layer comprising a invariable magnetization direction, the second nonmagnetic layer being on the second fixed layer, the second free layer being on the second nonmagnetic layer and comprising a variable magnetization direction;
wherein the first magnetoresistive effect element is on a first side of the lower electrode and electrically connected to the first side of the lower electrode, and
the second magnetoresistive effect element is on a second side of the lower electrode and electrically connected to the second side of the lower electrode.

5. The magnetic random access memory of claim 4, further comprising:
a third select transistor comprising a fourth diffusion region and a fifth diffusion region which are in the active region, the fourth diffusion region being electrically connected to the second free layer of the second magnetoresistive effect element; and
a second interconnect layer electrically connected to the second diffusion region and the fifth diffusion region.

6. The magnetic random access memory of claim 1, wherein
the active region is ladder-shaped when viewed from a direction perpendicular to the main surface of the semiconductor substrate.

7. The magnetic random access memory of claim 1, wherein
the active region comprises first, second and third rectangular regions, the first and second rectangular regions being longitudinally disposed in a first direction, the third rectangular region being between the first rectangular region and the second rectangular region in a second direction perpendicular to the first direction.

8. The magnetic random access memory of claim 7, wherein
the area of a memory cell comprising the first magnetoresistive effect element, the first select transistor and the second select transistor is 8 F² which is the product of dimensions in the first direction and the second direction when F is a minimum fabrication dimension.

9. The magnetic random access memory of claim 1, further comprising:
an interlayer insulating film between the semiconductor substrate and the first interconnect layer;
an upper electrode on the first free layer;
a first contact plug between the upper electrode and the first diffusion region;
a lower electrode under the first fixed layer; and
a first insulating film between the lower electrode and the first contact plug, the first insulating film comprising a material different from a material of the interlayer insulating film.

10. The magnetic random access memory of claim 9, wherein
the first insulating film comprises a silicon nitride film.

11. The magnetic random access memory of claim 1, further comprising:
an interlayer insulating film between the semiconductor substrate and the first interconnect layer;
a lower electrode under the first fixed layer;
a first contact plug between the lower electrode and the first interconnect layer;
an upper electrode on the first free layer; and
a first insulating film between the upper electrode and the first contact plug, the first insulating film comprising a material different from a material of the interlayer insulating film.

12. The magnetic random access memory of claim 11, wherein
the first insulating film comprises a silicon nitride film.

13. The magnetic random access memory of claim 1, wherein
a planar size of the first free layer is different from a planar size of the first fixed layer

14. The magnetic random access memory of claim 4, wherein
a combination of planar sizes of the first fixed layer and the second fixed layer is substantially the same as a planar size of the lower electrode.

15. The magnetic random access memory of claim 5, further comprising:
a third contact plug, a third interconnect layer and a fourth contact plug which are between the second and fifth diffusion regions and the second interconnect layer from the side of the second and fifth diffusion regions in order.

16. The magnetic random access memory of claim 5, further comprising:
a third contact plug, a fourth contact plug, a third interconnect layer and a fifth contact plug which are between the second and fifth diffusion regions and the second interconnect layer from the side of the second and fifth diffusion regions in order.

17. The magnetic random access memory of claim 1, wherein
the first, second and third diffusion regions comprise at least source regions or drain regions.

18. The magnetic random access memory of claim 5, wherein
the first, second, third, fourth and fifth diffusion regions comprise at least source regions or drain regions.
